(19) United States
(12) Patent Application Publication
(10) Pub. No.: US 2002/0109436 A1
(43) Pub. Date: Aug. 15, 2002

(54) Piezoelectrically actuated tunable electronic device

(76) Inventors: Cheng-Jien Peng, Hsinchu (TW); Tai-Kang Shing, Hsinchu (TW)

Correspondence Address: BACON & THOMAS, PLLC, 4th Floor, 625 Slaters Lane, Alexandria, VA, 22314-1176, US

(21) Appl. No.: 09/783,565

(22) Filed: Feb. 15, 2001

(51) Int. Cl. H01L 41/04

(52) U.S. Cl. 310/328; 310/348

(57) ABSTRACT

A piezoelectrically actuated electronic device comprises a substrate, a support and a first electrode provided on said support and a second electrode provided on said substrate, is disclosed. The support comprises a center portion and at least two elastic and symmetric arms, at least two piezoelectric films positioned on respective arms of said support and upper electrode and lower electrode for said piezoelectric films. The piezoelectric films are adhered firmly to the corresponding positions on the arms, relative to the center portion of said support, whereby extensions of the piezoelectric films will cause curving of said arms. By providing a voltage to said piezoelectric films, the length of the piezoelectric films will extend, such that the distance between said first electrode on said support and said second electrode on said substrate may be changed.

### FIELD OF INVENTION

The present invention relates to a piezoelectrically actuated tunable electronic device, especially to a multifunctional piezoelectrically actuated tunable electronic device. The piezoelectrically actuated tunable electronic device of this invention may function as a switch or a capacitor under the same structure.

### BACKGROUND OF INVENTION

There is a trend in the industry to prepare all kinds of electronic components by using the micromachining technology. Electronic components so prepared or disclosed include filters, microswitches, tunable capacitors etc. Components prepared by the micromachining technology provide advantages over the traditional components such as better electromechanical isolation, improved leakage in radio frequency (RF) circuits, declination in coupling with actuating circuits etc. Another advantage of such components is the low consumption of power. However, up to the present time, almost all microfabricated electronic components are driven by electrostatics or by induction mechanisms. In order to drive such components with electrostatic forces, a component such as a microswitch needs to be provided a high voltage of, for example, 30 V. (See Z. Jamie Yao et al., “Micromachined low-loss microwave switches”, IEEE. J. of Microelectromechanical Systems, Vol. 8, No. 2, p. 129-134 (1999).) Another disadvantage of such a component is that its structure tends to collapse, if the component is a tunable capacitor. (See E. K. Chan and R. W. Dutton, “Effects of capacitors, resistors and residual charge on the static and dynamic performance of electrostatically-actuated devices”, SPFE Vol. 3680, p. 120-130, 1999.) Although many researches and developments have been made to solve these problems, no industrially available solutions have been disclosed.

It is thus a need in the industry to provide a novel electronic component that can be driven effectively and rapidly. It is also a need to provide a novel microelectronic component wherein the problems in the conventional art may be solved.

### OBJECTIVES OF INVENTION

The objective of this invention is to provide a novel electronic component.

Another objective of this invention is to provide a piezoelectrically actuated tunable electronic device.

Another objective of this invention is to provide a simplified and multifunctional electronic device.

Another objective of this invention is to provide a piezoelectrically actuated electronic device wherein the corresponding surfaces of electrodes of the device may be maintained substantially parallel.

Another objective of this invention is to provide a method for the preparation of a novel electronic device.

### SUMMARY OF INVENTION

According to this invention, a novel piezoelectrically actuated electronic device is provided. The piezoelectrically actuated electronic device of this invention comprises a substrate, a support and a first electrode provided on said support and a second electrode provided on said substrate or another substrate. The support comprises a center portion and at least two elastic and symmetric arms, at least two piezoelectric films positioned on respective arms of said support and upper electrode and lower electrode for said piezoelectric films. The piezoelectric films are adhered firmly to the corresponding positions on the arms, relative to the center portion of said support, whereby extensions of the piezoelectric films will cause curving of said arms. By providing a voltage to said piezoelectric films, the length of the piezoelectric films will extend, such that the distance between said first electrode on said support and said second electrode on said substrate or another substrate may be changed.

When purpose of change of distance between said first electrode and said second electrode is to control the contact between said electrode and said second electrode, the piezoelectrically actuated electronic device functions as a microswitch. When purpose of change of distance between said first electrode and said second electrode is to control the distance between said electrode and said second electrode, the piezoelectrically actuated electronic device functions as a tunable capacitor. Since the arms of the support are in a symmetric manner, the corresponding surfaces of the first electrode and the second electrode may be maintained substantially parallel.

These and other objectives and advantages of this invention may be clearly understood from the detailed description by referring to the following drawings.

### BRIEF DESCRIPTION OF DRAWINGS

FIG. 1 illustrates the cross-sectional view of an embodiment of the piezoelectrically actuated electronic device of this invention.

FIG. 2 illustrates the cross-sectional view of another embodiment of the piezoelectrically actuated electronic device of this invention.

FIG. 3 illustrates the plan view of a third embodiment of the piezoelectrically actuated electronic device of this invention.

FIG. 4 illustrates the displacement of the arms of the piezoelectrically actuated electronic device of FIG. 3, as simulated in a computer software.

### DETAILED DESCRIPTION OF INVENTION

The following is a detailed description of the embodiments of the piezoelectrically actuated electronic device of this invention.

### EMBODIMENT I

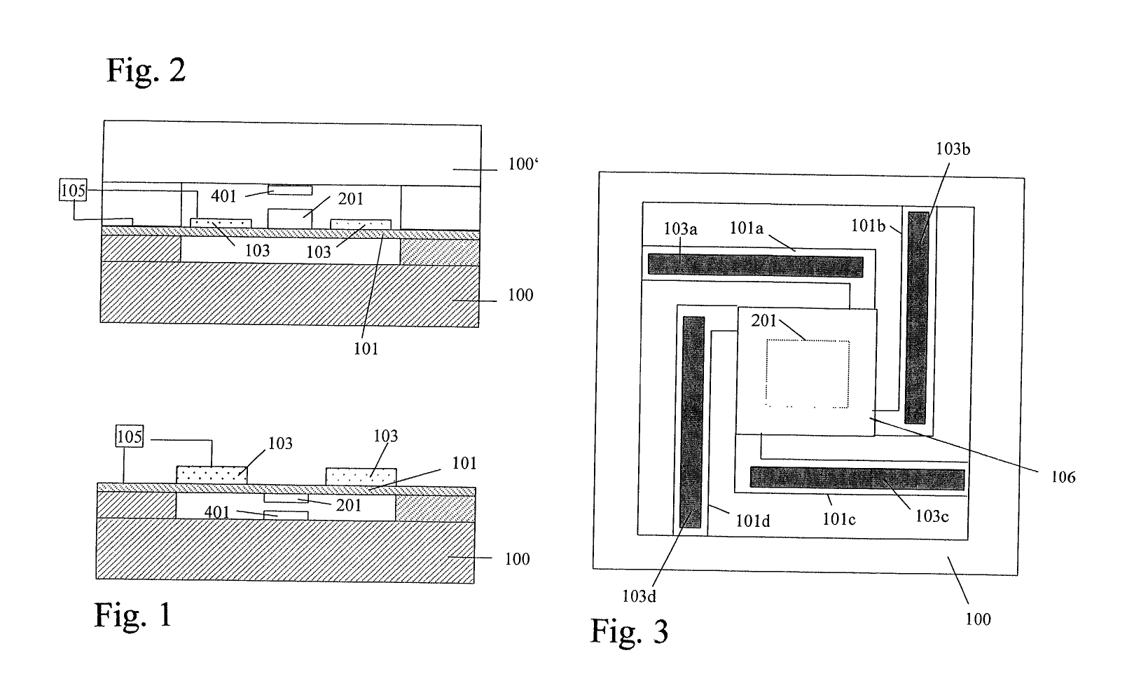

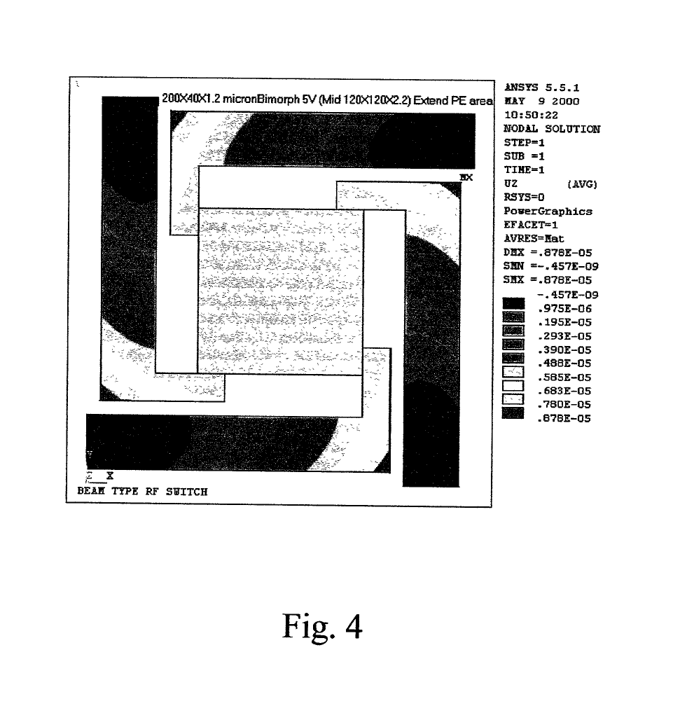

FIG. 1 illustrates the cross-sectional view of an embodiment of the piezoelectrically actuated electronic device of this invention. As shown in this figure, the piezoelectrically actuated electronic device of this invention comprises a substrate 100 to contain the piezoelectrically actuated electronic device and a support 101. The support 101 may be made of a strip of elastic material and comprises a central portion and two elastic arms 101a and 101b. Both ends of the support 101 are firmly positioned in the substrate 100, with its central portion being distanced to said substrate 100 at a predetermined distance. On the arms 101a and 101b of the support 101, firmly adhered are two piezoelectric films 103 and 103 at the corresponding position substantially symmetric to the central portion of the support 101. In this embodiment, the piezoelectric films 103 and 103 are in a strip shape. Above and beneath the piezoelectric films 103 and 103 are upper electrodes and lower electrodes (not shown) of the piezoelectric films 103, 103. The upper and lower electrodes of the piezoelectric films 103, 103 are supplied powers by a power supply (not shown) and the power supplied to said upper and lower electrodes are controlled by a controller 105.

On the surface of the central portion of the support 101 facing the substrate 100, a first electrode 201 is provided. On the surface of the substrate 100 facing the central portion of the support 101, a second electrode 401 is provided. Proper electric connections and necessary circuits to the first electrode 201 and the second electrode 401 are provided but are not shown in this figure. The connections and circuits for the first electrode 201 and the second electrode 410 may be easily understood by those skilled in the art by referring to the following descriptions. Detailed description thereof is thus omitted.

When a voltage is supplied to the upper and lower electrodes of the piezoelectric films 103, 103, the length of the piezoelectric films 103, 103 will be extended according to the voltage as supplied, substantially in proportion to the voltage supplied. Since the piezoelectric films are firmly adhered to the arms 101a and 101b, the extension of length of the piezoelectric films 103, 103 will cause the arms 101a and 101b to bend, thereby the distance between the first electrode 201 and the second electrode 410 will be decreased. When sufficient voltage is supplied, the bending of the arms 101a and 101b may cause the contact between the first electrode 201 and the second electrode 401. When voltage supplied to the upper and lower electrodes of the piezoelectric films 103, 103 is stopped, the arms 101a and 101b will return to their respective original shape. As such, the distance or the contact between the first electrode 201 and the second electrode 401 may be controlled by controlling the voltage supplied to the upper and lower electrodes of the piezoelectric films 103, 103.

Since the two piezoelectric films 103, 103 are positioned at substantially symmetric positions relative to the central portion of the support 101, during the bending of the arms 103, 103, the corresponding surfaces of the first electrode 201 and the second electrode 401 are maintained substantially parallel.

Based on such design, the space between the first electrode 201 and the second electrode 401 can be varied and function as a tunable capacitor. The capacitance between the electrodes 201, 401 may be adjusted by the controller 105. On the other hand, the electrodes 201 and 401 may be controlled to contact with each other and function as a microswitch. The contact between the electrodes 201 and 401 may be controlled by said controller 105.

Since the first electrode 201 and the second electrode 401 may be maintained substantially parallel during the control, enhanced adjustment or switching effects may be obtained, either as a tunable capacitor or a microswitch.

In the preparation of the piezoelectrically actuated electronic device of this invention, the support 101 may be prepared with a semi-insulator and/or insulation material under the micro fabrication technology or under the surface micromachining technology. The actuator of the tunable electronic device is the piezoelectric films 103, 103. In application, the films may contain one or tow layers of piezoelectric material. If more than two layers are used, each layer may contain its respective upper electrode and lower electrode. Applicable piezoelectric material includes ZnO, AlN, PZT or other piezoelectric materials.

### EMBODIMENT II

FIG. 2 illustrates the cross-sectional view of another embodiment of the piezoelectrically actuated electronic device of this invention. In this figure, elements that are the same with that in FIG. 1 are labeled with same numbers.

As shown in FIG. 2, the major difference between this embodiment with Embodiment I rests in that two substrates are provided. The second electrode 401 is provided on the second substrate 100′, not on the first substrate 100. As a result, supplying a voltage to the upper and lower electrodes of the piezoelectric films 103, 103 will cause the distance between the first electrode 201 and the second electrode 401 to increase. Other aspects and way of control for this embodiment are substantially the same as that for Embodiment I.

### EMBODIMENT III

FIG. 3 illustrates the plan view of a third embodiment of the piezoelectrically actuated electronic device of this invention. In this figure, elements that are the same with that in FIGS. 1 and 2 are labeled with same numbers.

As shown in this figure, the major difference between this embodiment and that of Embodiments I and II rests in that a support 101 provided with 4 arms 101a, 101b, 101c and 101d. The 4 arms 101a-101d supportively connect to a floating plate 106. The first electrode 201 is positioned beneath the floating plate 106, facing the second electrode 401. Piezoelectric films 103a, 103b, 103c and 103d are respectively provided on respective arms 101a, 101b, 101c and 101d.

In this embodiment, the arms in combination form a Buddhism cross ( [symbol] ). The 4 piezoelectric films 103a-103d are respectively positioned on the arms 101a-101d at symmetric positions relative to the center of the floating plate 106. By supplying a voltage to the piezoelectric films 103a-103d simultaneously, the first electrode 201 may move toward the second electrode 401, even to contact the second electrode 401. During the movement of the first electrode 201, the corresponding surfaces of the first electrode 201 and the second electrode 401 may be maintained substantially parallel.

When a PZT film is used in the piezoelectrically actuated electronic device of this invention, by supplying a 5 V to the piezoelectric film, about 6 μm displacement may be actuated. FIG. 3 illustrates the displacement of the arms of the piezoelectrically actuated electronic device of Embodiment III, as simulated in a computer software. In this figure, shown is the displacement of the arms when the size of the arms 101a-101d is 200*40*1.2 (μm). The piezoelectric films are 0.3 μm in thickness and the first and the second electrodes are 0.2 μm in thickness.

In some embodiments of this invention, a stress sensing device (not shown) may be provided on the stress sensitive positions of the arms. A feedback circuit may be provided to control the voltage supplied to the electrodes of the piezoelectric films to more specifically control the variation of the arms. In such an application, the stress generated by the downward bending of the arms may be sensed to be deemed the variation of the arms.

In this invention, the arms are provided substantially symmetric to the central portion of the support. As a result, the corresponding surfaces of the first electrode and the second electrode may be maintained substantially parallel.

Although in the description of the embodiments, the support in the shape of a strip (with two arms) and a Buddhism cross (with four arms) is taken for example, other shape of support with substantially symmetric arms may be suited in this invention. These may include tripod shape, circular shape, radiation shape etc.

As the present invention has been shown and described with reference to preferred embodiments thereof those skilled in the art will recognize that the above and other changes may be made therein without departing form the spirit and scope of the invention.

What is claimed is:

1. A piezoelectric tunable electronic device comprising:
a substrate;
a support comprising a central portion and at least two elastic arms extending from said central portion and in a substantially symmetric arrangement relative to said central portion wherein an end of said elastic arms is fixed to said substrate, with said central portion distanced to said substrate at a predetermined distance;
a first electrode positioned on said central portion of said support;
a second electrode positioned on said substrate, facing said central portion of said support; and
at least two piezoelectric films adhered to said at least two arms of said support respectively at positions substantially symmetrically to said central portion of said support;
whereby, by applying a voltage to said piezoelectric films, the distance between said first electrode and said electrode may be changed.

2. The piezoelectric tunable electronic device according to claim 1 wherein said support comprises an elastic strip.

3. The piezoelectric tunable electronic device according to claim 1 wherein said support comprises at least 3 elastic arms extending from said central portion.

4. The piezoelectric tunable electronic device according to claim 1, further comprising a second substrate positioned above said support, wherein said second electrode is positioned on said second substrate, facing said central portion of said support.

5. The piezoelectric tunable electronic device according to claim 3 wherein said support further comprises a plate to support said first electrode.
